(19) United States
(12) Patent Application Publication
(10) Pub. No.: US 2025/0285975 A1
(43) Pub. Date: Sep. 11, 2025

(54) ENHANCED POWER RAIL CONNECTION

(71) Applicant: International Business Machines Corporation, Armonk, NY (US)

(72) Inventors: HUIMEI ZHOU, Albany, NY (US); Ravikumar Ramachandran, Pleasantville, NY (US); LEI ZHUANG, Ridgefield, CT (US); Ruilong Xie, Niskayuna, NY (US); Xiaoming Yang, Clifton Park, NY (US); Eric Miller, Albany, NY (US); Mahender Kumar, Clifton Park, NY (US)

(21) Appl. No.: 18/599,807

(22) Filed: Mar. 8, 2024

(51) Int. Cl. H01L 23/528; H01L 21/8234; H01L 23/532; H01L 27/088; H01L 29/06; H01L 29/08; H01L 29/423; H01L 29/66; H01L 29/786

(52) U.S. Cl. CPC H01L 23/5286; H01L 23/5283; H01L 23/53238; H10D 30/6735; H10D 30/6757; H10D 62/115; H10D 62/118; H10D 62/151; H10D 64/017; H10D 84/013; H10D 84/0149; H10D 84/038; H10D 84/83

(57) ABSTRACT

A semiconductor structure with a power rail between at least two front side semiconductor devices and a connector via connecting the power rail to a backside metal layer of a backside power delivery network. The connector via resides within a shallow isolation trench. The connector via has a top surface that is below the top surface of the shallow isolation trench. The connector via provides a direct connection between the power rail connecting to at least one of the front side semiconductor devices and the backside power delivery network.

### BACKGROUND

The disclosure generally relates to forming a semiconductor device and more particularly, to advanced semiconductor devices with power rails and backside power delivery networks.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. For logic device and memory device scaling at the two-nanometer node, planar and non-planar semiconductor device structures, such as metal-oxide-semiconductor field-effect transistors (MOSFETs), must be scaled to smaller dimensions.

As the semiconductor industry continues to drive to the two-nanometer technology node with tighter pitches and smaller device elements with increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. A backside power delivery network improves semiconductor device gate delay and reduces BEOL wiring congestion.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure including a power rail and a connector via connecting the power rail to a backside metal layer where the connector via is within a shallow isolation trench.

Aspects of the disclosed invention relate to a semiconductor structure with a connector via. In embodiments, the connector via is a copper element with a trapezoidal cross-section. The connector via has a larger width of the top surface of the connector via than the width of the bottom surface of the connector via. A portion of a power rail is directly above and contacting the top surface of the connector via. The power rail extends between the gates of at least two adjacent semiconductor devices. A backside metal layer of a backside power delivery network contacts the bottom surface of the connector via.

Aspects of the disclosed invention relate to a semiconductor structure with a connector via. The connector via is a copper element with a trapezoidal cross-section that is in the bottom portion of a shallow isolation trench. The connector via has a top surface with a larger width than the width of the bottom surface of the connector via. A liner is on the sidewall of the connector via. A power rail is directly above and contacts the top surface of the connector via. The power rail between the gate of at least two adjacent semiconductor devices. A backside metal layer contacts the bottom surface of the connector via.

Aspects of the disclosed invention relate to a method of forming a semiconductor structure that includes etching a hole between two portions of a nanosheet stack where the hole extends to the bottom surface of a shallow isolation trench (STI). The method includes a deposition of a liner in the hole. The method includes removing horizontal portions of the liner with a directional etching process and growing a placeholder using epitaxy in the bottom portion of the hole. The top surface of the placeholder is below the top surface of the STI. The method includes removing exposed portions of the liner. The method includes depositing and recessing an oxide. A portion of the oxide remains on the placeholder. The method includes forming source/drains using epitaxy and forming replacement metal gates. The method includes forming a power rail with a power rail liner contacting the placeholder. The method includes forming gate and source/drain contacts, where one source/drain contact connects to the power rail. The method includes removing the backside substrate, the etch stop layer, and portions of the semiconductor material directly under the STIs. The method includes removing a portion of the deposited backside interlayer dielectric exposing the bottom surface of the placeholder and then, removing the placeholder. The method includes depositing and patterning the backside interlayer dielectric and depositing a metal layer on the backside interlayer dielectric and in the hole created by the removal of the placeholder. The portion of the deposited metal layer in the hole created by the removal of the placeholder is a connector via and the portion of the metal layer in the backside interlayer dielectric is the first backside metal layer of the backside power delivery network.

Aspects of the disclosed invention relate to a method of forming a semiconductor structure that includes etching a hole between two portions of a nanosheet stack where the hole extends to the bottom of a shallow isolation trench (STI). A first liner is deposited over the semiconductor structure. The method includes removing horizontal portions of the first liner with a directional etching process and depositing a second liner. The method includes removing horizontal portions of the second liner. The method includes growing a placeholder using epitaxy in a portion of the hole. The top surface of the placeholder is below the top surface of the STI. The method includes removing exposed portions of the first and second liners. The method includes depositing and recessing an oxide. A portion of the oxide remains on the placeholder. The method includes forming source/drains using epitaxy and forming replacement metal gates. The method includes forming a power rail with a liner contacting the placeholder. The method includes forming gate and source/drain contacts, where one source/drain contact connects to the power rail. The method includes removing a backside substrate, an etch stop layer, and portions of a semiconductor material. The method includes removing a portion of a deposited backside interlayer dielectric exposing the bottom surface of the placeholder and then, removing the placeholder. The method includes removing a portion of a deposited backside interlayer dielectric exposing the bottom surface of the placeholder and then, removing the placeholder. The method includes forming a connector via by depositing a metal in the hole created by the removed placeholder and forming a backside metal layer on the connector via. The connector via connects the backside metal layer of a backside power delivery network to the power rail on the front side of a semiconductor substrate.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a top view of an illustration of a semiconductor design, in accordance with an embodiment of the present invention.

FIG. 2 depicts a cross-sectional view Y1-Y1 of a semiconductor structure after depositing a dielectric isolation material over two nanosheet stacks, in accordance with an embodiment of the present invention.

FIG. 3 depicts a cross-sectional view Y1-Y1 of the semiconductor structure after depositing a first liner, patterning for a power rail etch, and etching the power rail opening, in accordance with an embodiment of the present invention.

FIG. 4 depicts a cross-sectional view Y1-Y1 of the semiconductor structure after optionally removing horizontal portions of the first liner, in accordance with an embodiment of the present invention.

FIG. 5 depicts a cross-sectional view Y1-Y1 of the semiconductor structure after optionally forming an additional thickness of the first liner and removing horizontal portions of the thicker liner, in accordance with an embodiment of the present invention.

FIG. 6 depicts a cross-sectional view Y1-Y1 of the semiconductor structure after growing a placeholder on the bottom surface of the power rail opening, in accordance with an embodiment of the present invention.

FIG. 7 depicts a cross-sectional view Y1-Y1 of the semiconductor structure after removing exposed surfaces of the liner, in accordance with an embodiment of the present invention.

FIG. 8 depicts a cross-sectional view Y1-Y1 of the semiconductor structure after depositing an oxide, performing a CMP, and recessing the oxide, in accordance with an embodiment of the present invention.

FIG. 9 depicts a top view of the semiconductor structure with the placeholder, in accordance with an embodiment of the present invention.

FIG. 10A depicts a cross-sectional view X1-X1 of the semiconductor structure after forming the dummy gates, in accordance with an embodiment of the present invention.

FIG. 10B depicts a cross-sectional view Y1-Y1 of the semiconductor structure after forming the dummy gates, in accordance with an embodiment of the present invention.

FIG. 10C depicts a cross-sectional view Y2-Y2 of the semiconductor structure after forming the dummy gates, in accordance with an embodiment of the present invention.

FIG. 11A depicts a cross-sectional view X1-X1 of the semiconductor structure after depositing an interlayer dielectric (ILD), in accordance with an embodiment of the present invention.

FIG. 11B depicts a cross-sectional view Y1-Y1 of the semiconductor structure after using epitaxy to grow the placeholder and depositing the ILD, in accordance with an embodiment of the present invention.

FIG. 11C depicts a cross-sectional view Y2-Y2 of the semiconductor structure after using epitaxy to form the placeholders and depositing the ILD, in accordance with an embodiment of the present invention.

FIG. 12A depicts a cross-sectional view X1-X1 of the semiconductor structure after removing dummy gate material and sacrificial layers, in accordance with an embodiment of the present invention.

FIG. 12B depicts a cross-sectional view Y1-Y1 of the semiconductor structure after forming removing dummy gate material and sacrificial layers, in accordance with an embodiment of the present invention.

FIG. 12C depicts a cross-sectional view Y2-Y2 of the semiconductor structure after removing dummy gate material and sacrificial layers, in accordance with an embodiment of the present invention.

FIG. 13A depicts a cross-sectional view X1-X1 of the semiconductor structure after forming replacement metal gates, in accordance with an embodiment of the present invention.

FIG. 13B depicts a cross-sectional view Y1-Y1 of the semiconductor structure after forming the replacement metal gates, in accordance with an embodiment of the present invention.

FIG. 13C depicts a cross-sectional view Y2-Y2 of the semiconductor structure after forming the replacement metal gates, in accordance with an embodiment of the present invention.

FIG. 14A depicts a cross-sectional view X1-X1 of the semiconductor structure after etching an opening for a power rail, in accordance with an embodiment of the present invention.

FIG. 14B depicts a cross-sectional view Y1-Y1 of the semiconductor structure after etching the opening for the power rail, in accordance with an embodiment of the present invention.

FIG. 14C depicts a cross-sectional view Y2-Y2 of the semiconductor structure after etching the opening for the power rail, in accordance with an embodiment of the present invention.

FIG. 15A depicts a cross-sectional view X1-X1 of the semiconductor structure after depositing a liner for the power rail, in accordance with an embodiment of the present invention.

FIG. 15B depicts a cross-sectional view Y1-Y1 of the semiconductor structure after depositing the liner for the power rail, in accordance with an embodiment of the present invention.

FIG. 15C depicts a cross-sectional view Y2-Y2 of the semiconductor structure after depositing the liner for the power rail, in accordance with an embodiment of the present invention.

FIG. 16 depicts a top view of an illustration of the semiconductor design with the power rail, in accordance with an embodiment of the present invention.

FIG. 16A depicts a cross-sectional view X1-X1 of the semiconductor structure after depositing a power rail metal, in accordance with an embodiment of the present invention.

FIG. 16B depicts a cross-sectional view Y1-Y1 of the semiconductor structure after depositing the power rail metal, in accordance with an embodiment of the present invention.

FIG. 16C depicts a cross-sectional view Y2-Y2 of the semiconductor structure after depositing power rail metal, in accordance with an embodiment of the present invention.

FIG. 17A depicts a cross-sectional view X1-X1 of the semiconductor structure after depositing another layer of ILD, in accordance with an embodiment of the present invention.

FIG. 17B depicts a cross-sectional view Y1-Y1 of the semiconductor structure after depositing another layer of ILD, in accordance with an embodiment of the present invention.

FIG. 17C depicts a cross-sectional view Y2-Y2 of the semiconductor structure after depositing another layer of ILD, in accordance with an embodiment of the present invention.

FIG. 18A depicts a cross-sectional view X1-X1 of the semiconductor structure after patterning a layer of OPL and etching source/drain (S/D) contact holes, in accordance with an embodiment of the present invention.

FIG. 18B depicts a cross-sectional view Y1-Y1 of the semiconductor structure after patterning OPL and etching gate contact holes, in accordance with an embodiment of the present invention.

FIG. 18C depicts a cross-sectional view Y2-Y2 of the semiconductor structure after patterning OPL and etching S/D contact holes, in accordance with an embodiment of the present invention.

FIG. 19A depicts a cross-sectional view X1-X1 of the semiconductor structure after forming contacts, in accordance with an embodiment of the present invention.

FIG. 19B depicts a cross-sectional view Y1-Y1 of the semiconductor structure after forming contacts, in accordance with an embodiment of the present invention.

FIG. 19C depicts a cross-sectional view Y2-Y2 of the semiconductor structure after forming contacts, in accordance with an embodiment of the present invention.

FIG. 20A depicts a cross-sectional view X1-X1 of the semiconductor structure after depositing layers of ILD, forming vias, forming one or more metal layers, and front side interconnect wiring, in accordance with an embodiment of the present invention.

FIG. 20B depicts a cross-sectional view Y1-Y1 of the semiconductor structure after depositing layers of ILD, forming vias, forming one or more metal layers, and front side interconnect wiring, in accordance with an embodiment of the present invention.

FIG. 20C depicts a cross-sectional view Y2-Y2 of the semiconductor structure after depositing layers of ILD, forming vias, forming one or more metal layers, and front side interconnect wiring, in accordance with an embodiment of the present invention.

FIG. 21A depicts a cross-sectional view X1-X1 of the semiconductor structure after removing the semiconductor substrate and etch stop layer, in accordance with an embodiment of the present invention.

FIG. 21B depicts a cross-sectional view Y1-Y1 of the semiconductor structure after removing the semiconductor substrate and etch stop layer, in accordance with an embodiment of the present invention.

FIG. 21C depicts a cross-sectional view Y2-Y2 of the semiconductor structure after removing the semiconductor substrate and the etch stop layer, in accordance with an embodiment of the present invention.

FIG. 22A depicts a cross-sectional view X1-X1 of the semiconductor structure after removing portions of the semiconductor material and further recessing portions of the semiconductor material between adjacent shallow trench isolations (STIs), in accordance with an embodiment of the present invention.

FIG. 22B depicts a cross-sectional view Y1-Y1 of the semiconductor structure after removing portions of the semiconductor material and further recessing portions of the semiconductor material between adjacent STIs, in accordance with an embodiment of the present invention.

FIG. 22C depicts a cross-sectional view Y2-Y2 of the semiconductor structure after removing portions of the semiconductor material and further recessing portions of the semiconductor material between the STIs, in accordance with an embodiment of the present invention.

FIG. 23A depicts a cross-sectional view X1-X1 of the semiconductor structure after depositing a backside ILD, in accordance with an embodiment of the present invention.

FIG. 23B depicts a cross-sectional view Y1-Y1 of the semiconductor structure after depositing the backside ILD, in accordance with an embodiment of the present invention.

FIG. 23C depicts a cross-sectional view Y2-Y2 of the semiconductor structure after depositing the backside ILD, in accordance with an embodiment of the present invention.

FIG. 24A depicts a cross-sectional view X1-X1 of the semiconductor structure after patterning and etching openings in the backside ILD, in accordance with an embodiment of the present invention.

FIG. 24B depicts a cross-sectional view Y1-Y1 of the semiconductor structure after depositing another layer of ILD, in accordance with an embodiment of the present invention.

FIG. 24C depicts a cross-sectional view Y2-Y2 of the semiconductor structure after patterning and etching openings in the backside ILD, in accordance with an embodiment of the present invention.

FIG. 25A depicts a cross-sectional view X1-X1 of the semiconductor structure after removing the placeholder, in accordance with an embodiment of the present invention.

FIG. 25B depicts a cross-sectional view Y1-Y1 of the semiconductor structure after removing the placeholder, in accordance with an embodiment of the present invention.

FIG. 25C depicts a cross-sectional view Y2-Y2 of the semiconductor structure after removing the placeholder, in accordance with an embodiment of the present invention.

FIG. 26A depicts a cross-sectional view X1-X1 of the semiconductor structure after forming the first backside metal layer, in accordance with an embodiment of the present invention.

FIG. 26B depicts a cross-sectional view Y1-Y1 of the semiconductor structure after forming the first backside metal layer, in accordance with an embodiment of the present invention.

FIG. 26C depicts a cross-sectional view Y2-Y2 of the semiconductor structure after forming the first backside metal layer, in accordance with an embodiment of the present invention.

FIG. 27B depicts a cross-sectional view Y1-Y1 of the semiconductor structure without the thicker liner after forming the first backside metal layer, in accordance with an embodiment of the present invention.

FIG. 27C depicts a cross-sectional view Y2-Y2 of the semiconductor structure without the thicker liner after forming the first backside metal layer, in accordance with an embodiment of the present invention.

### DETAILED DESCRIPTION

Embodiments of the present invention recognize that overlay misalignment and high aspect ratios of vias and power rails create increased resistance or a reduction in voltage such as a drop in current times resistance (IR drop) that degrades semiconductor device and chip electrical performance, especially in semiconductor devices using backside wiring and backside power delivery networks (BSPDN). Semiconductor device designs using semiconductor fabrication processes that reduce overlay shifts and decrease the aspect ratios in vias and power rails would improve semiconductor device and chip electrical performance.

Aspects of the present invention provide semiconductor devices and methods of forming semiconductor devices with a connector via that directly connects a power rail extending above and below the semiconductor devices to a backside metal layer of a backside power delivery network.

In aspects of the present invention, the connector via is formed from a placeholder in a bottom portion of a shallow trench isolation (STI). The trench for forming the placeholder is etched from the front side of the semiconductor structure. The placeholder, grown by epitaxy, fills a bottom portion of the trench. The top surface of the placeholder is below the top surface of the STI.

A power rail, extending between adjacent semiconductor devices, can be formed directly on the placeholder using known semiconductor fabrication processes. After depositing a backside interlayer dielectric (ILD) and forming openings in the backside ILD for backside metal lines and vias, the connector via is formed by removing the placeholder with a backside etching process and depositing a metal, such as copper, for both the connector via and the first backside metal layer in opening in the STI created by the removal of the placeholder and in the openings created in the backside ILD. Using these processes where a placeholder is formed in a portion of an STI, and then later replaced by a backside metal such as copper provides a semiconductor structure that directly connects a power rail to the first backside metal layer by the connector via that is in a portion of the STI.

An aspect ratio is the ratio of the width of a hole to the depth of the hole where, in general, a lower aspect ratio hole is easier to form. Front side vias were introduced as one type for BSPDN connection. Because of a higher aspect ratio for the front side vias that are to be extended to at least the STI, an additional via connection was also introduced to improve or reduce the aspect ratio. However, forming the additional connection from the front side vias to the BSPDN is challenging for alignment. Further scaling or size reduction of the semiconductor devices would be gated if the additional via connection was processed from backside. Processing the additional via connection from the backside creates overlay concerns. An overlay refers to the alignment accuracy of two or more layers or masks during the fabrication process. Overlay is the process of precisely aligning multiple layers of a chip on top of each other to create the desired pattern. The overlay control largely determines the minimum feature size that may be incorporated into semiconductor device design.

The present invention uses a placeholder created to connect the front side devices and wiring and the backside wiring of the BSPDN. Using the placeholder which will be removed and replaced to form the connection between front side devices and wiring to the BSPDN by a connector via, improves the front side via process by providing a lower aspect ratio for the front side via. In various embodiments, the front side or front via is called a power rail or a front side power rail residing between adjacent semiconductor devices. Additionally, using the placeholder created from the front side of the wafer and then, replaced with the backside contact metal using a self-aligned process, improves the semiconductor process yields and the overlay concerns with conventional connections between the front side wiring and the BSPDN.

The semiconductor devices can be logic or memory semiconductor devices using the connector via to connect at least one source/drain of the semiconductor device to the power rail. The connector via directly contacts the BSPDN and the power rail which is connected to at least one source/drain of a semiconductor device. The semiconductor device(s) can be logic devices such as a gate-all-around field-effect device, a finFET, a planar FET, a stacked FET including a complimentary FET, another type of logic device, or a memory device including one or more stacked memory devices.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process followed by one or more etching processes. Some examples of etching processes include but are not limited to the following processes, such as a dry etching process using a reactive ion etch (RIE) or ion beam etch (IBE), a wet chemical etch process, or a combination of these etching processes.

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to device element scale.

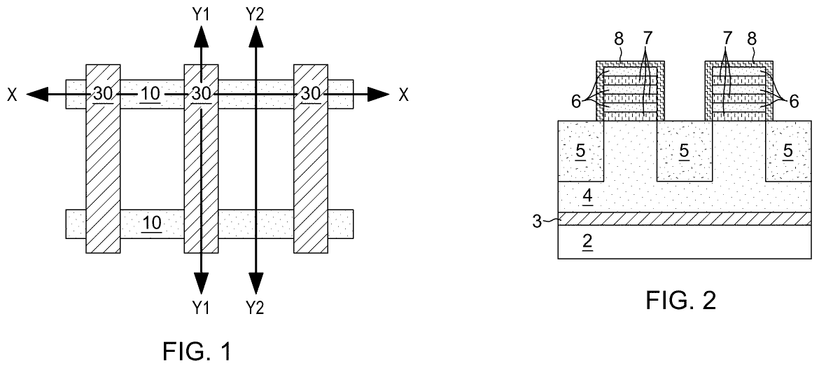

FIG. 1 depicts a top view of an illustration of semiconductor design, in accordance with an embodiment of the present invention. As depicted, FIG. 1 includes active region 10, gate structures 30, and power rail 26 with liner 27 where FIG. 1 depicts one example of two field-effect transistors (FETs). While FIG. 1 depicts one example of a semiconductor device design, in other examples, another type of one or more logic semiconductor designs or one or more of memory device designs can be used with the processes discussed later in embodiments of the present invention.

FIG. 1 also illustrates the location of cross-sectional views Y1-Y1 parallel to and through one of gate structures 30 and the location of cross-sectional views Y2-Y2 that are parallel to and between two adjacent gate structures 30. Also, illustrated in FIG. 1 is the location of cross-sectional views X1-X1 in the top active region 10 that is perpendicular to gate structures 30, cross-sectional views Y1-Y1, and cross-sectional views Y2-Y2.

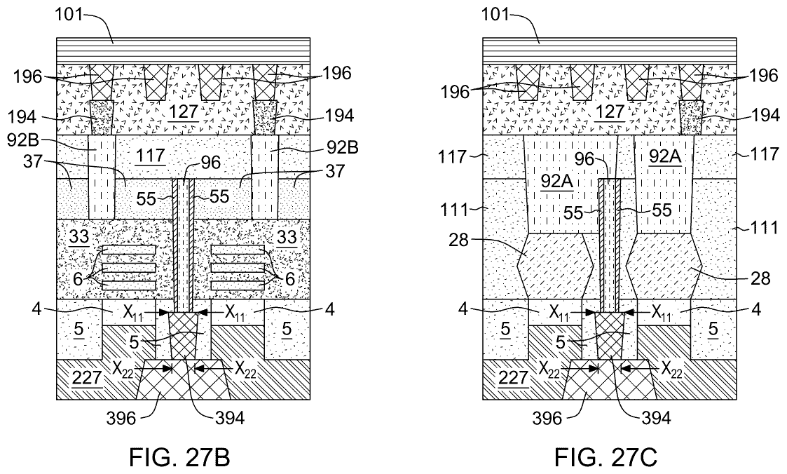

As depicted, the semiconductor design illustrates two semiconductor devices which may be two logic devices (e.g., two GAA FETs as depicted in FIGS. 27B and 27C) or two memory devices. In some embodiments, the two semiconductor devices are two or more stacked semiconductor devices (e.g., stacked FETs, complimentary FETs, or stacked memory devices).

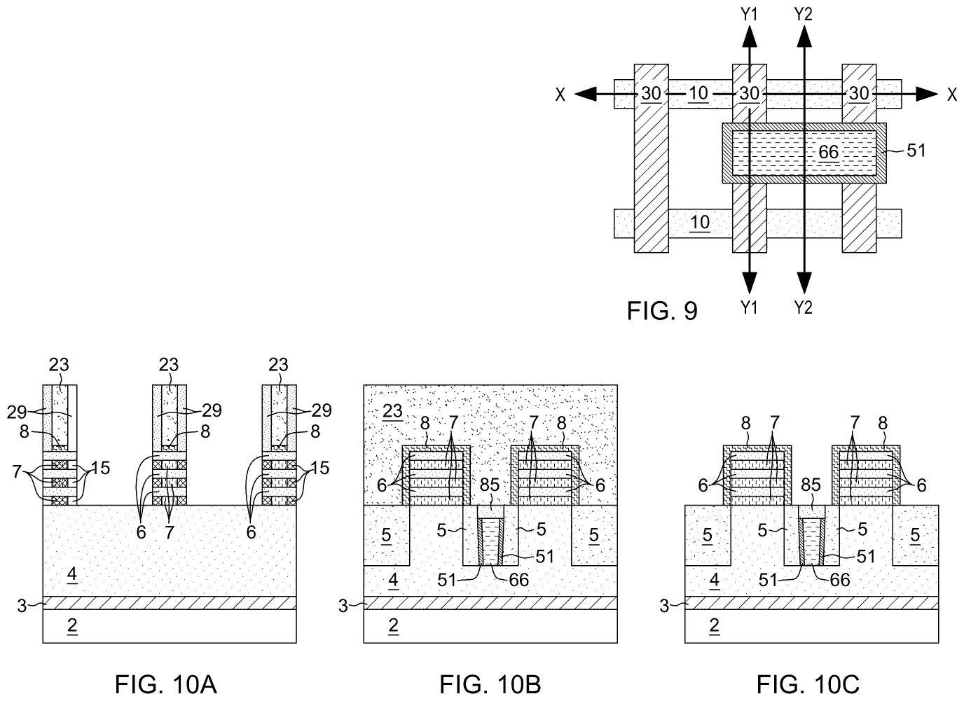

In the Figures beyond FIG. 9, cross-sectional views X1-X1 are illustrated in the FIGS. identified with the letter “A”; cross-sectional views Y1-Y1 are illustrated in the FIGS. identified with the letter “B”; cross-sectional views Y2-Y2 are illustrated in the FIGS. identified with the letter “C”.

FIG. 2 depicts a cross-sectional view Y1-Y1 of a semiconductor structure after depositing dielectric isolation 8 over two nanosheet stacks composed of alternating nanosheet layers of channels 6 and sacrificial material 7, in accordance with an embodiment of the present invention. As depicted, FIG. 2 includes substrate 2 under etch stop 3, semiconductor material 4 on etch stop 3, shallow trench isolations (STIs) 5 in portions of semiconductor material 4, and two nanosheet stacks with alternating layers of sacrificial material 7 and channels 6 on semiconductor material 4 with dielectric isolation 8 covering exposed surfaces of the nanosheet stacks. As depicted, the two nanosheet stacks on semiconductor material 4 are above and between STIs 5. Sacrificial material 7 can be SiGe but is not limited to SiGe. Channels 6 can be silicon but is not limited to this semiconductor material. Substrate 2 and semiconductor material 4 can be silicon but are not limited to this semiconductor material. Dielectric isolation 8 can be any dielectric material used in semiconductor devices such as but not limited to SiO₂.

While FIG. 2 depicts a nanosheet structure to form two gate-all-around FETs (GAA FETs), a different semiconductor structure for forming a different type of logic device such as but not limited to planar FETs, finFETs, complementary FETs, stacked FETs or one or more memory devices including stacked memory devices.

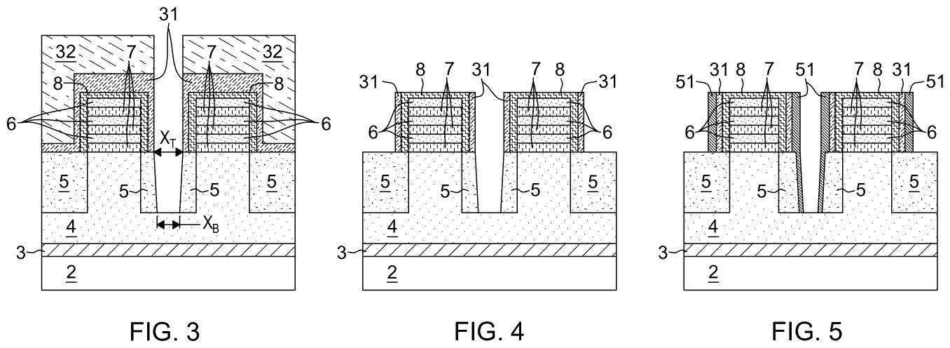

FIG. 3 depicts a cross-sectional view Y1-Y1 of the semiconductor structure after depositing liner 31, patterning organic planarization layer (OPL) 32 for a power rail etch, and etching the power rail opening, in accordance with an embodiment of the present invention. As depicted, FIG. 3 includes the elements of FIG. 2 without a portion of the middle STI 5 and the addition of liner 31 and the patterned OPL 32. Also, included in FIG. 3 are widths Xₜ and X_{b} where Xₜ is the width of the top portion of the etched opening or trench between the two sides of the middle STI 5 and X_{b} is the width of the bottom portion of the etched opening between the two sides of the middle STI 5. The width Xₜ is slightly greater than the width X_{b} due to the etching process forming a portion of the opening. For example, a RIE etching process from the top surface of OPL 32 down to stop at semiconductor material 4 can create the opening or trench etched through the middle STI 5 with a slightly narrowing opening or hole as the opening extends down from OPL 32 to semiconductor material 4.

In various embodiments, liner 31 is composed of SiN but is not limited to this liner material. Liner 31 deposits on the top surfaces of STI 5 and sidewall of dielectric isolation 8 in the semiconductor structure depicted in FIG. 4 prior to the trench etching process. After depositing liner 31, the opening for the trench is etched in the middle STI 5. As depicted, the trench etching process stops at semiconductor material 4.

FIG. 4 depicts a cross-sectional view Y1-Y1 of the semiconductor structure after removing OPL 32 and horizontal portions of liner 31, in accordance with an embodiment of the present invention. As depicted, FIG. 4 includes the elements of FIG. 3 without OPL 32 and the horizontal portions of liner 31.

After depositing the layer of liner 31 and performing an RIE to remove the horizontal portions of liner 31 on dielectric isolation 8 and semiconductor material 4, liner 31 remains on the almost vertical sidewall with the middle STI 5.

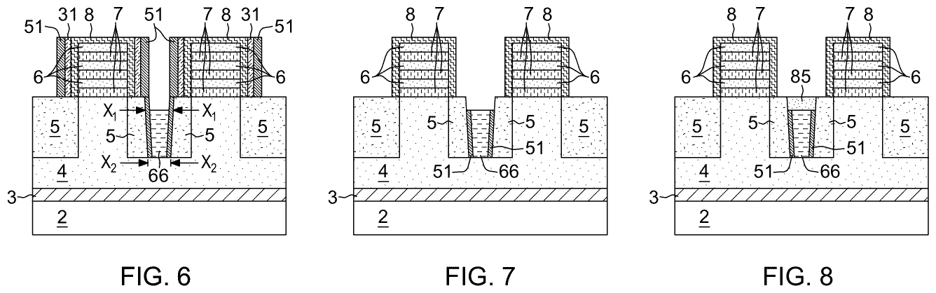

This semiconductor structure can be used to produce the semiconductor structures of FIG. 27B and FIG. 27C when the second layer of liner material for liner 51 is not deposited on the sidewall of the middle STI 5 in the processes of FIG. 5. When liner 51 is not deposited on the sidewall of STI 5 by skipping the process steps depicted in FIG. 5, a wider placeholder 66 epitaxially grown on semiconductor material 4 resulting in the wider connector via 394 depicted in FIGS. 27B and 27C. To form the semiconductor structure of FIGS. 27B and 27C, the optional process step of FIG. 5 is not performed. FIGS. 27B and 27C can be formed with the semiconductor structure of FIG. 4 after skipping the process steps of FIG. 5 and then, performing the remaining process steps after FIG. 5 (e.g., performing the process steps of FIG. 6 and the remaining process steps to form FIGS. 27B and 27C).

FIG. 5 depicts a cross-sectional view Y1-Y1 of the semiconductor structure after optionally forming a second liner 51 on the first liner 31 and removing horizontal portions of liner 51, in accordance with an embodiment of the present invention. As depicted, FIG. 5 includes the elements of FIG. 4 with liner 51 on the exposed sidewalls of liner 31. Liner 51 can be the same material as liner 31 (e.g., SiN). In one embodiment, liner 51 is a different liner material than liner 31. A RIE may remove any horizontal portions liner 51 on semiconductor material 4 and dielectric isolation 8.

FIG. 6 depicts a cross-sectional view Y1-Y1 of the semiconductor structure after growing placeholder 66 on the exposed portion of semiconductor material 4 in the opening between the two nanosheet stacks of channels 6 and sacrificial material 7 covered by dielectric isolation 8, in accordance with an embodiment of the present invention. As depicted, FIG. 6 includes the elements of FIG. 5 with the addition of placeholder 66. Also, illustrated in FIG. 6 are widths X₁ and X₂ where X₁ is the width of the top surface of placeholder 66 and width X₂ is the width of the bottom portion of placeholder 66.

Using epitaxy, placeholder 66 grows on a portion of semiconductor material 4 between liner 51 on the middle STI 5. As depicted in FIG. 6, the top surface of placeholder 66 is below the top surface of semiconductor material 4 and STI 5. The bottom of placeholder 66 resides on STI 5 and is level with the bottom portion of STI 5. As depicted in FIG. 6, the width X₁ of placeholder 66 could be smaller than 80 percent of the distance between the two nanosheet stacks. The cross-sectional view of placeholder 66 is slightly tapered and has a trapezoidal shape that is slightly wider at the top. Accordingly, X₁ which is the width of the top surface of placeholder 66 is slightly greater than X₂ which is the width of the bottom surface of placeholder 66.

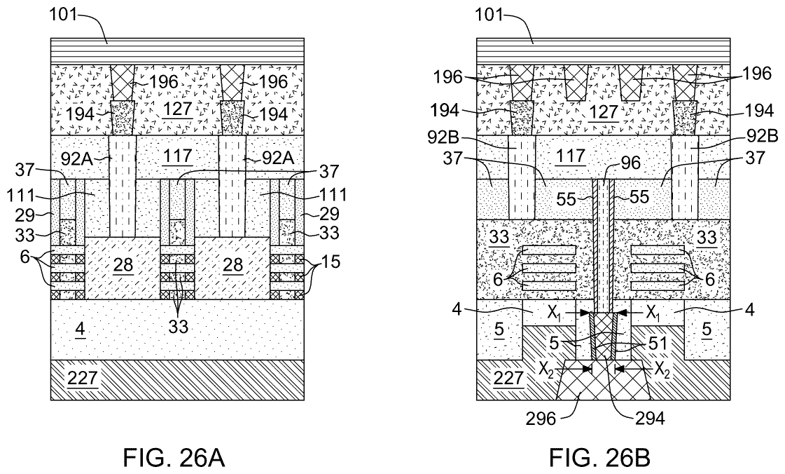

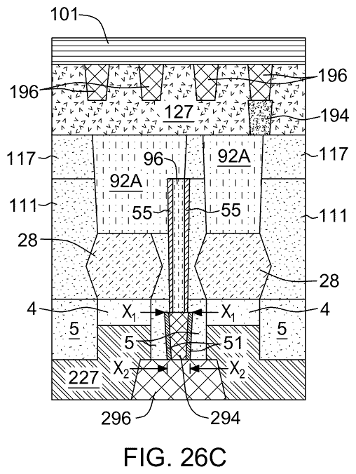

In some embodiments, epitaxy grows placeholder 66 on semiconductor material 4 in the semiconductor structure of FIG. 4. FIG. 4 does not have liner 51 and in these embodiments, placeholder 66 contacts the sidewall of the middle STI 5. Without liner 51 on STI 5, placeholder 66 is wider. Using this embodiment with the processes discussed with respect to FIGS. 6-25C results in the semiconductor structure depicted in FIGS. 27B and 27C. This embodiment with a wider placeholder 66 provides better electrical performance in the semiconductor structure of FIGS. 27B and 27C compared to the semiconductor structure of FIGS. 26B and 26C due the wider connector via 394 depicted in FIGS. 27B and 27C compared to connector via 294 depicted in FIGS. 26B and 26C. As discussed later, connector via 394 in FIGS. 27B and 27C replaces the placeholder grown in the opening in the middle STI 5 of FIG. 4 without liner 51 and connector via 294 can be formed by replacing placeholder 66 grown in the opening over semiconductor material 4 in the middle STI 5 of FIG. 6.

FIG. 7 depicts a cross-sectional view Y1-Y1 of the semiconductor structure after removing exposed surfaces of liner 51, in accordance with an embodiment of the present invention. As depicted, FIG. 7 includes the elements of FIG. 6 without the exposed portions of liner 51. Using one or more known dry or wet etching processes for removing liner materials (e.g., SiN), the exposed portions of liner 51 on the sidewalls of dielectric isolation 8 and on the remaining portions of the middle STI 5 are removed. Portions of liner 51 between placeholder 66 and STI 5 remain.

FIG. 8 depicts a cross-sectional view Y1-Y1 of the semiconductor structure after depositing dielectric 85, performing a CMP, and recessing dielectric 85, in accordance with an embodiment of the present invention. As depicted, FIG. 8 includes the elements of FIG. 7 with dielectric 85. Using a known deposition process such as CVD or PVD, a layer of dielectric 85 is deposited over the semiconductor structure. Dielectric 85 can be SiO₂, for example. CMP can planarize the surface of dielectric 85 and an etching process such as RIE removes portions of dielectric 85 above the surface of STI 5. A portion of dielectric 85 remains over placeholder 66 with liner 51 with a surface that is level with the surface of STI 5.

FIG. 9 depicts a top view of an illustration of the semiconductor design with placeholder 66 and liner 51, in accordance with an embodiment of the present invention. As depicted, FIG. 9 includes two active regions 10, three gate structures 30, and placeholder 66 with liner 51. Also, illustrated in FIG. 9 are the locations of cross-sectional views X1-X1, Y1-Y1, and Y2-Y2. In FIG. 9, the top view of placeholder 66 with liner 51 has a rectangular shape with a longer horizontal length parallel to active regions 10 than the vertical width of placeholder 66. As depicted in FIG. 9, placeholder 66 extends just beyond and between two of gate structures 30. Placeholder 66 resides between active regions 10 and is parallel to active regions 10.

FIG. 10A depicts a cross-sectional view X1-X1 of the semiconductor structure after forming dummy gates with dummy gate material 23, gate spacer 29, and inner spacers 15, in accordance with an embodiment of the present invention. As depicted, FIG. 10A includes substrate 2, etch stop 3, semiconductor material 4, channels 6, sacrificial material 7, dielectric isolation 8, inner spacers 15, gate spacer 29, and dummy gate material 23 where dummy gate material 23 is typically polysilicon.

As known to one skilled in the art, dummy gates, can include dummy gate material 23 (e.g., polysilicon), inner spacers 15 (e.g., SiN), and gate spacers 29 and are formed using known semiconductor processes.

FIG. 10B depicts a cross-sectional view Y1-Y1 of the semiconductor structure after forming the dummy gates, in accordance with an embodiment of the present invention. As depicted, FIG. 10B includes substrate 2, etch stop 3, semiconductor material 4, channels 6, sacrificial material 7, dielectric isolation 8, dummy gate material 23, three STIs 5 where the middle STI 5 includes placeholder 66 with liner 51 in a bottom portion of the middle STI 5, and dielectric 85 over placeholder 66 with liner 51. Dummy gate material 23 can be deposited on the exposed surfaces of STI 5, dielectric isolation 8, and dielectric 85.

FIG. 10C depicts a cross-sectional view Y2-Y2 of the semiconductor structure after forming the dummy gates depicted in the cross-sectional views of FIG. 10A and FIG. 10B, in accordance with an embodiment of the present invention. As depicted, FIG. 10C includes the elements of FIG. 8.

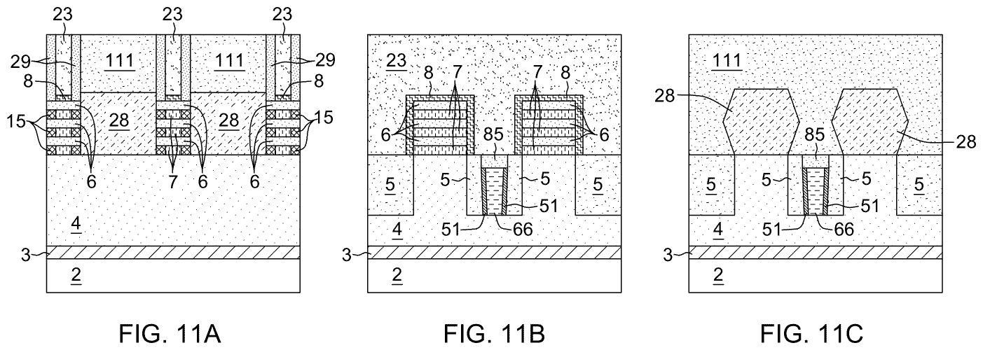

FIG. 11A depicts a cross-sectional view X1-X1 of the semiconductor structure after growing S/D 28 on exposed portions of semiconductor material 4, and depositing ILD 13, in accordance with an embodiment of the present invention. As depicted, FIG. 11A includes the elements of FIG. 10A with S/D 28 and ILD 111.

Using known epitaxy processes, two S/D 28 can be grown on exposed surfaces of channels 6 and semiconductor material 4 between the remaining portions of the nanosheet stacks. In FIG. 11A, the top surface of S/D 28 is above the top channel of channels 6 and slightly above dielectric isolation 8. Using PVD, CVD, or another known dielectric deposition process, ILD 111 can be deposited on S/D 28, gate spacers 29, and dummy gate material 23. A CMP can planarize the top surface and remove excess ILD 111 over dummy gate material 23.

FIG. 11B depicts a cross-sectional view Y1-Y1 of the semiconductor structure after growing S/D 28 using epitaxy and depositing the ILD in FIG. 11A and FIG. 11C, in accordance with an embodiment of the present invention. As depicted, FIG. 11B is the same as FIG. 10B.

FIG. 11C depicts a cross-sectional view Y2-Y2 of the semiconductor structure after removing portions of channels 6, sacrificial material 7, dielectric isolation 8 over portions of semiconductor material 4 rising between the three STIs 5, growing epitaxy for S/D 28 and depositing ILD 111, in accordance with an embodiment of the present invention. As depicted, FIG. 11C includes the elements of FIG. 10C without portions of the two nanosheet stacks and with the addition of ILD 111 and S/D 28. S/D 28 epitaxially grows on exposed portions of semiconductor material 4 after removing portions of the two nanosheet stacks composed of channels 6, sacrificial material 7, and dielectric isolation 8 (e.g., using RIE and/or IBE). S/D 28 can be epitaxially grown and doped in various embodiments. After forming two S/D 28, a layer of ILD 111 can be deposited and a CMP performed. ILD 111 can be an oxide (e.g., SiO₂) or another material used for an interlayer dielectric.

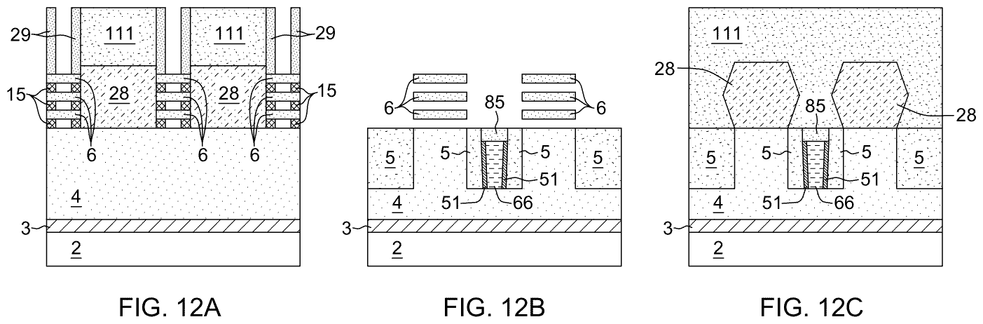

FIG. 12A depicts a cross-sectional view X1-X1 of the semiconductor structure after removing dummy gate material 23 and sacrificial material 7, in accordance with an embodiment of the present invention. As depicted, FIG. 12A includes the elements of FIG. 11A without dummy gate material 23 and sacrificial material 7. Using known dummy gate removal processes and sacrificial material 7 etching processes, sacrificial material 7 and dummy gate material 23 are removed.

FIG. 12B depicts a cross-sectional view Y1-Y1 of the semiconductor structure after removing dummy gate material 23, dielectric isolation 8, and sacrificial material 7, in accordance with an embodiment of the present invention. Using known dummy gate removal processes and sacrificial material 7 etching processes, sacrificial material 7 and dummy gate material 23 are removed.

FIG. 12C depicts a cross-sectional view Y2-Y2 of the semiconductor structure after removing dummy gate material 23 and sacrificial material 7 in FIGS. 12A and 12B, in accordance with an embodiment of the present invention. As depicted, FIG. 12C is the same as FIG. 11C.

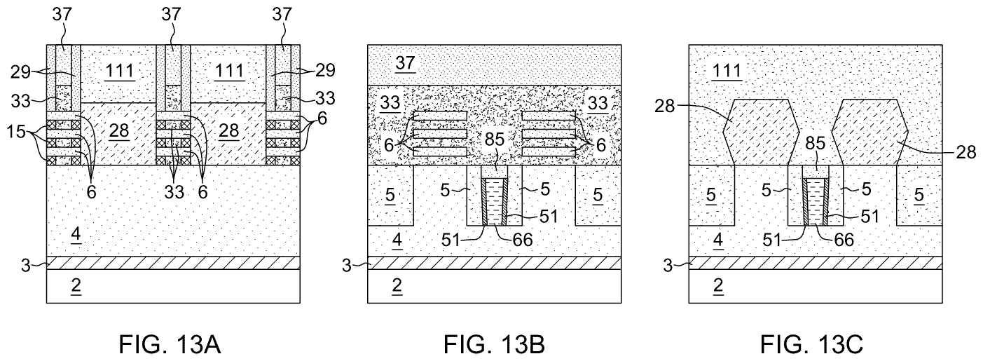

FIG. 13A depicts a cross-sectional view X1-X1 of the semiconductor structure after forming replacement metal gates (RMG), in accordance with an embodiment of the present invention. As depicted, FIG. 13A includes the elements of FIG. 12A without dummy gate material 23, with replacement metal gates that include gate 33 over a gate dielectric material (not depicted) replacing dummy gate material 23, inner spacers 15, and gate spacers 29. Dielectric 37 can be deposited over exposed to surfaces of gate 33 where gate 33 can be composed of at least a work function metal over a high-k gate dielectric (not depicted). As known to one skilled in the art, the replacement metal gate structure includes gate 33 with gate spacers 29 and inner spacers 15. In various embodiments, dielectric 37 is SiN but is not limited to this material.

FIG. 13B depicts a cross-sectional view Y1-Y1 of the semiconductor structure after forming the replacement metal gates, in accordance with an embodiment of the present invention. As depicted, FIG. 13B includes the elements of FIG. 12B with gate 33 and dielectric 37 over gate 33. In various embodiments, a layer of a gate dielectric material (not depicted) is deposited (e.g., by ALD) on the exposed surfaces of FIG. 12B before gate 33 deposition (e.g., by CVD, PVD, or ALD).

FIG. 13C depicts a cross-sectional view Y2-Y2 of the semiconductor structure after forming the replacement metal gates, in accordance with an embodiment of the present invention. As depicted, FIG. 13C is the same as FIG. 12C.

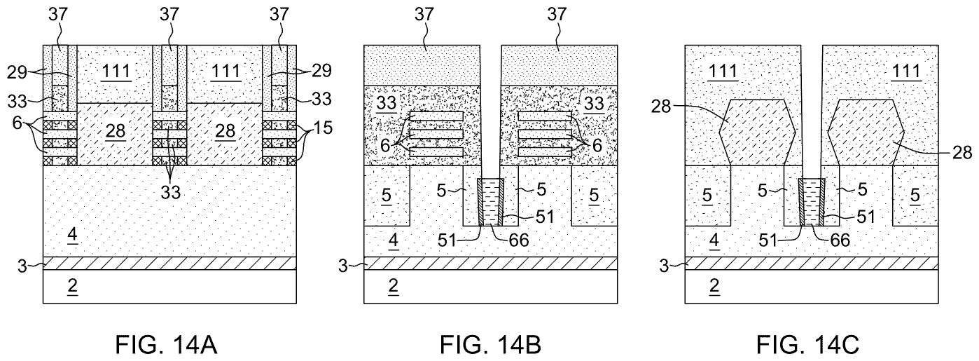

FIG. 14A depicts a cross-sectional view X1-X1 of the semiconductor structure after etching an opening for a power rail, in accordance with an embodiment of the present invention. As depicted, FIG. 14A is the same as FIG. 13A.

FIG. 14B depicts a cross-sectional view Y1-Y1 of the semiconductor structure after etching the opening for the power rail, in accordance with an embodiment of the present invention. As depicted, FIG. 14B includes the elements of FIG. 13B without a portion of dielectric 37, gate 33, and dielectric 85. Using known patterning and etching processes, the trench for the power rail can be etched above placeholder 66 and the etching process stops at the top surface of placeholder 66.

FIG. 14C depicts a cross-sectional view Y2-Y2 of the semiconductor structure after etching the opening for the power rail, in accordance with an embodiment of the present invention. As depicted, FIG. 14C includes the elements of FIG. 13C without a portion of ILD 111 and dielectric 85 over placeholder 66. Using the processes discussed above with reference to FIG. 14B, the opening or trench can be formed above the top surface of placeholder 66. As depicted, the opening can be etched in ILD 111 between the two adjacent S/D 28.

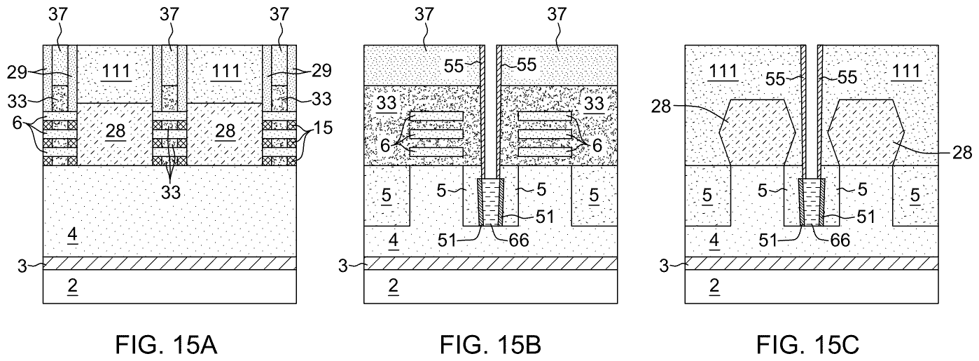

FIG. 15A depicts a cross-sectional view X1-X1 of the semiconductor structure after depositing liner 55 for the power rail in FIGS. 15B and 15C, in accordance with an embodiment of the present invention. As depicted, FIG. 15 includes the same elements as FIG. 14A.

FIG. 15B depicts a cross-sectional view Y1-Y1 of the semiconductor structure after depositing liner 55 for the power rail, in accordance with an embodiment of the present invention. As depicted, FIG. 15B includes liner 55 on the sidewall of the opening in dielectric 37 and gate 33. Liner 55 can be composed of a dielectric material suitable for a power rail liner (e.g., SiBCN, SiN, AlOx). Using known semiconductor processes, a thin layer of liner 55 can be deposited (e.g., by ALD) and a dry directional etching process such as RIE removes the horizontal portions of liner 55 on the surface of placeholder 66 and ILD 111.

Compared to a conventionally etched opening or trench for a power rail, the etching process depicted in FIGS. 15B and 15C stops at the top surface of placeholder 66 which is below the top surface of STI 5. A lower aspect ratio hole can be used in the embodiments of the present invention due to the presence of placeholder 66. Providing placeholder 66 with a slightly increased width compared to the width of the opening for the power rail (e.g., power rail 96 in FIG. 26B) in the middle STI 5, the additional connection via decreasing the front side via height, the additional connection via reduces the need for a high aspect ratio hole or trench for the connection of the BSPDN (not depicted) with power rail 96 (not depicted in FIG. 15B).

FIG. 15C depicts a cross-sectional view Y2-Y2 of the semiconductor structure after depositing the liner for the power rail, in accordance with an embodiment of the present invention. As depicted, FIG. 15C includes the elements of FIG. 14C with liner 55. Liner 55 can be formed with the processes discussed with respect to FIG. 15B.

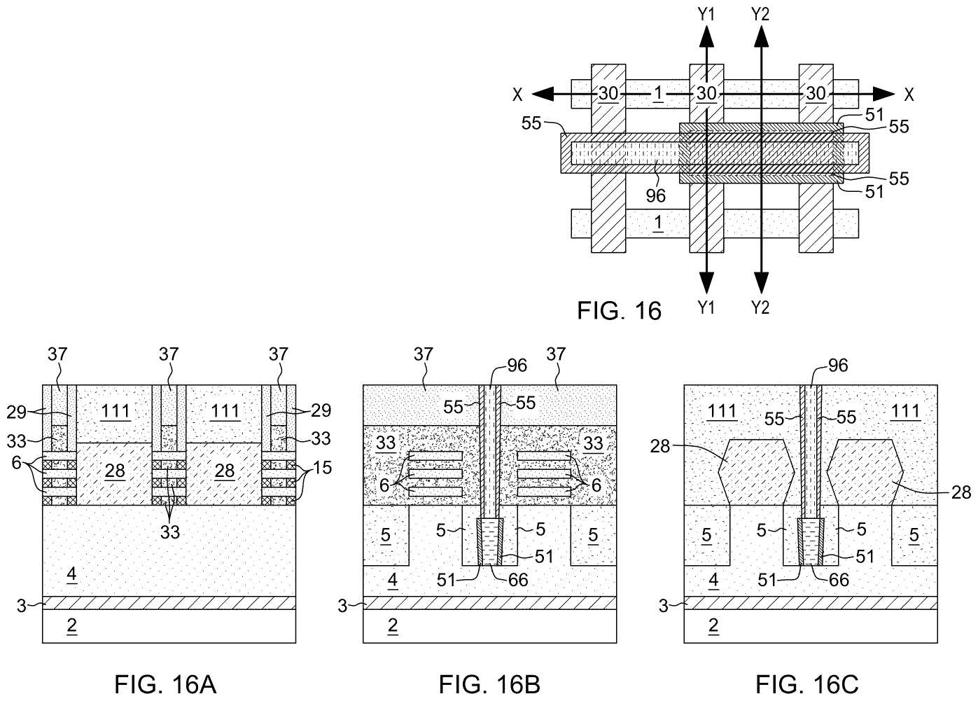

FIG. 16 depicts a top view of an illustration of the semiconductor design with two semiconductor devices and power rail 96 and placeholder 66, in accordance with an embodiment of the present invention. As depicted, FIG. 16 includes two active regions 10, gate structures 30, power rail 96 with liner 55, placeholder 66 with liner 51 below power rail 96. In some embodiments, power rail 96 is a front side via or a front via. As depicted in FIG. 16, power rail 96 extends across three gate structures 30, and placeholder 66 extends between two adjacent gate structure 30. As depicted in FIG. 16, the top view of placeholder 66 has a longer horizontal length extending slightly beyond two adjacent gate structures 30 the width depicted between active regions 10. Placeholder 66 below a portion of power rail 26 extends below and between two of gate structures 30. Placeholder 66 is wider than power rail 26 and shorter than power rail 26 in the horizontal direction (i.e., parallel to active regions 10). Also, depicted in FIG. 16 are the locations of cross-sectional views X1-X1, Y1-Y1, and Y2-Y2.

FIG. 16A depicts a cross-sectional view X1-X1 of the semiconductor structure after depositing the power rail metal and performing a CMP to form power rail 96 (not depicted in FIG. 16A), in accordance with an embodiment of the present invention. As depicted, FIG. 16A has the same elements as FIG. 15A.

FIG. 16B depicts a cross-sectional view Y1-Y1 of the semiconductor structure after depositing the power rail metal and performing the CMP to form power rail 96, in accordance with an embodiment of the present invention. As depicted, FIG. 16B includes the elements of FIG. 15B with power rail 96. The power rail metal deposition of one of W, Mo, Ru, or Co, for example, can occur using known deposition processes such as CVD, ALD, or PVD. After the CMP, power rail 96 with liner 55, as depicted in FIG. 16B, resides between the two adjacent gates 33, the remaining portions of the two nanosheet stacks (e.g., channels 6 in gate 33, and dielectric 37. In some embodiments, power rail 96 is front via connecting to placeholder 66 and extending between multiple gates. A portion of power rail 96 with liner 55 extends down into the top portion of the middle STI 5. The bottom surface of power rail 96 contacts the top surface of placeholder 66. The top surface of power rail 96 is above gate 33 and is level with the top surface of dielectric 37. As depicted, the sidewalls of power rail 96 are electrically isolated from gate 33 by liner 55.

FIG. 16C depicts a cross-sectional view Y2-Y2 of the semiconductor structure after depositing the power rail metal and performing the CMP to form power rail 96, in accordance with an embodiment of the present invention. As depicted, FIG. 16C includes the elements of FIG. 15C with power rail 96. Using the known materials and processes discussed with respect to FIG. 16B, power rail 96 with liner 55 is formed contacting the top surface of placeholder 66 and between two adjacent S/D 28. In FIG. 16C, a portion of ILD 111 separates ILD 111 from each of S/D 28, in other examples, liner 55 can separate and electrically isolate power rail 96 from one or both of S/D 28. As depicted, power rail 96 with liner 55 is between the two of S/D 28.

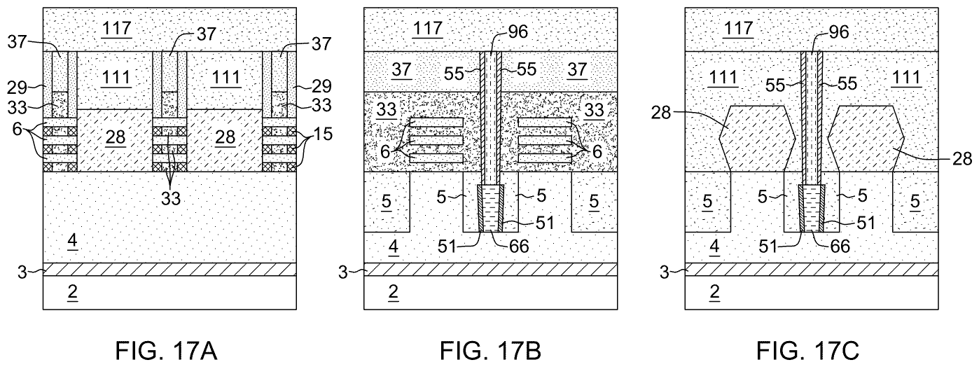

FIG. 17A depicts a cross-sectional view X1-X1 of the semiconductor structure after depositing ILD 117, in accordance with an embodiment of the present invention. As depicted, FIG. 17A includes the elements of FIG. 16A with ILD 117 over ILD 111, dielectric 37, and gate spacer 29. A CMP can be performed.

FIG. 17B depicts a cross-sectional view Y1-Y1 of the semiconductor structure after depositing ILD 117, in accordance with an embodiment of the present invention. Using known deposition processes (e.g., CVD), depositing ILD 117 on the exposed surfaces of dielectric 37, liner 55, and power rail 96.

FIG. 17C depicts a cross-sectional view Y2-Y2 of the semiconductor structure after depositing ILD 117, in accordance with an embodiment of the present invention. As depicted in FIG. 17C, ILD 117 deposits over ILD 111, liner 55, and power rail 96.

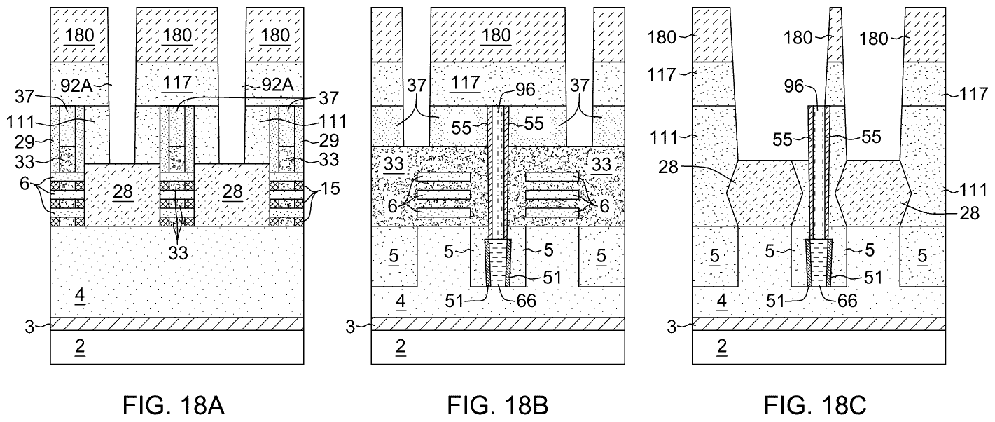

FIG. 18A depicts a cross-sectional view X1-X1 of the semiconductor structure after patterning OPL 180 and etching source/drain (S/D) contact holes, in accordance with an embodiment of the present invention. As depicted, FIG. 18A includes the elements of FIG. 17A with patterned OPL 180, and without portions of ILD 117, ILD 111, dielectric 37, over a portion of each of S/D 28. Using known lithography and etching processes (e.g., RIE), an opening contacting each S/D 28 can be formed for an S/D contact hole.

FIG. 18B depicts a cross-sectional view Y1-Y1 of the semiconductor structure after patterning OPL 180 and etching gate contact holes, in accordance with an embodiment of the present invention. As depicted, FIG. 18B includes the elements of FIG. 17B without portions of ILD 117 and dielectric 37 over each of gate 33. After patterning OPL 180, using one or more known etching processes for oxide removal and then, dielectric 37 removal (e.g., a nitride etch), two holes for a gate contact can be formed. Each hole contacts the top surface of one of gate 33.

FIG. 18C depicts a cross-sectional view Y2-Y2 of the semiconductor structure after patterning OPL 180 and etching S/D contact holes, in accordance with an embodiment of the present invention. As depicted, FIG. 18C includes the elements of FIG. 17C without portions of OPL 180, ILD 117, and ILD 111 above at least the top surface of each of S/D 28.

Using known processes for S/D contact hole etching for the two GAA FET devices, an S/D contact hole can be formed for each of the two S/D 28. The rightmost contact hole is over and contacting the top surface of the rightmost S/D 28, as depicted, and extends up above the top surface of ILD 117.

A slightly larger and angled S/D contact hole can be etched (e.g., with a slightly angled IBE) over the leftmost S/D 28 where the larger contact hole exposes the top surface of the left S/D 28 and most of the top surface of power rail 96 and portions of liner 55. In other words, the portion of power rail 96 with liner 55 adjacent to the left S/D 28 is exposed in FIG. 18C. The portion of liner 55 adjacent to the rightmost S/D 28 is covered by ILD 111 above and adjacent to the leftmost S/D 28.

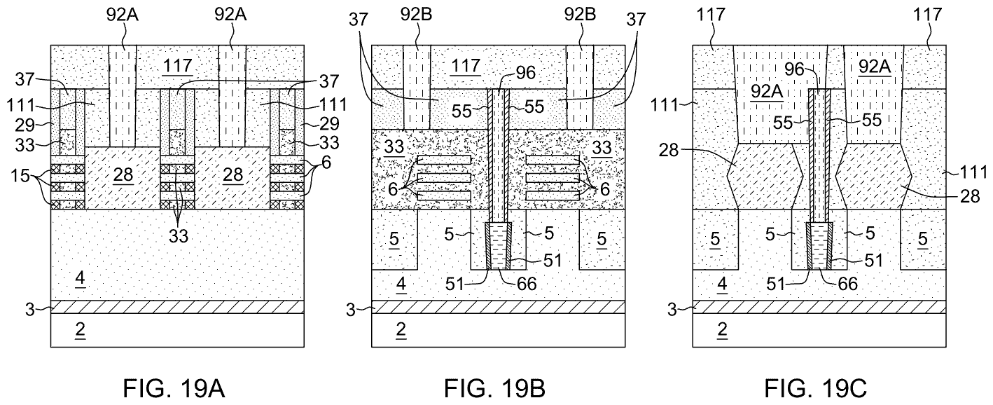

FIG. 19A depicts a cross-sectional view X1-X1 of the semiconductor structure after forming contacts 92A, in accordance with an embodiment of the present invention. As depicted, FIG. 19A includes the element of FIG. 18A with a contact metal filling the S/D contact hole to form two of contact 92A that are S/D contacts. Contacts 92A each contact the top surface of one of two adjacent S/D 28, as depicted. After contact metal (e.g., W, Cu, Ru, Co) deposition using known processes, CMP planarizes the semiconductor surface top surface and removes the excess contact metal.

FIG. 19B depicts a cross-sectional view Y1-Y1 of the semiconductor structure after forming contacts 92B, in accordance with an embodiment of the present invention. As depicted, contacts 92B (e.g., gate contacts) are formed using the processes discussed above. Each of contact 92B contacts a portion of the top surface of one of gate 33.

FIG. 19C depicts a cross-sectional view Y2-Y2 of the semiconductor structure after forming contacts 92A, in accordance with an embodiment of the present invention. Using the processes discussed with respect to FIG. 19A, each of contact 92A connecting to one of S/D 28 can be formed. The leftmost contact 92A in FIG. 19C also connects to a portion of the exposed top surface of power rail 96. Using conventional processes, the leftmost S/D contact labeled contact 92A has a bottom surface connecting to the left S/D 28 and another portion of the bottom surface above S/D 28 and connecting to the exposed portion of the top surface of power rail 96. The right contact 92A connects to the top surface of the right S/D 28.

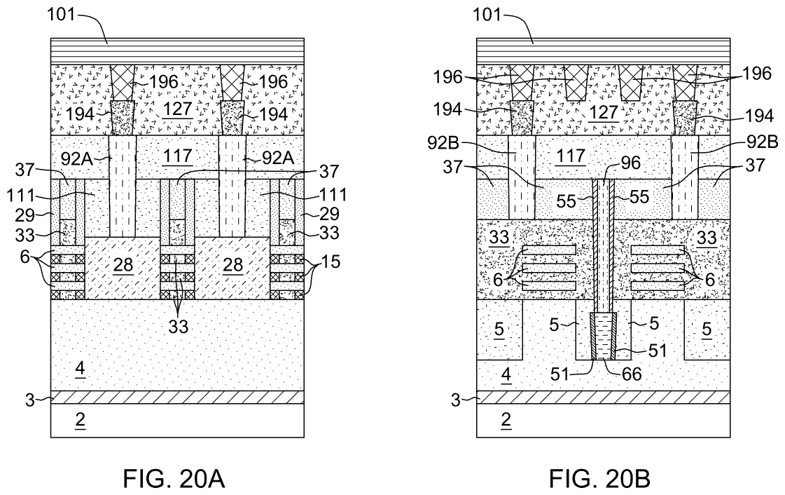

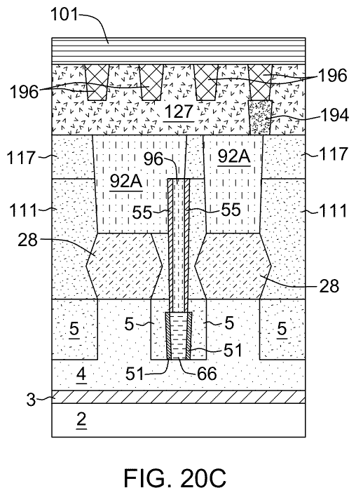

FIG. 20A depicts a cross-sectional view X1-X1 of the semiconductor structure after depositing layers of ILD 127, forming vias 194 and 196, and forming one or more layers of front side interconnect wiring 101, in accordance with an embodiment of the present invention. As depicted, FIG. 20A includes the elements of FIG. 19A with ILD 127, vias 194 connecting contacts 92A to metal layer 196, and front side interconnect wiring 101.

Using known semiconductor fabrication processes for via formation, metal layer formation, and back end of line (BEOL) semiconductor processes, one or more layers of ILD 127 deposits on ILD 117 and contacts 92A. Using known processes, vias 194 and metal layer 196 can be formed to connect to the created front side interconnect wiring 101. In FIG. 20A, each of S/D 28 connects by contact 92A, via 194, and a portion of metal layer 196 to front side interconnect wiring 101.

FIG. 20B depicts a cross-sectional view Y1-Y1 of the semiconductor structure after depositing layers of ILD 127, forming vias 194 and 196, and forming front side interconnect wiring 101, in accordance with an embodiment of the present invention. Using the processes discussed above with reference to FIG. 20A, each of gates 33 connect by contact 92B to via 194, and metal layer 196 to front side interconnect wiring 101.

FIG. 20C depicts a cross-sectional view Y2-Y2 of the semiconductor structure after depositing layers of ILD 127, forming vias 194 and 196, and forming front side interconnect wiring 101, in accordance with an embodiment of the present invention. Using the previously discussed known via and BEOL processes, the rightmost S/D contact 28 connects by contact 92A to via 194, to metal layer 196, and front side interconnect wiring 101. The leftmost S/D 28 connects by the leftmost contact 92A to power rail 96 which is directly above placeholder 66.

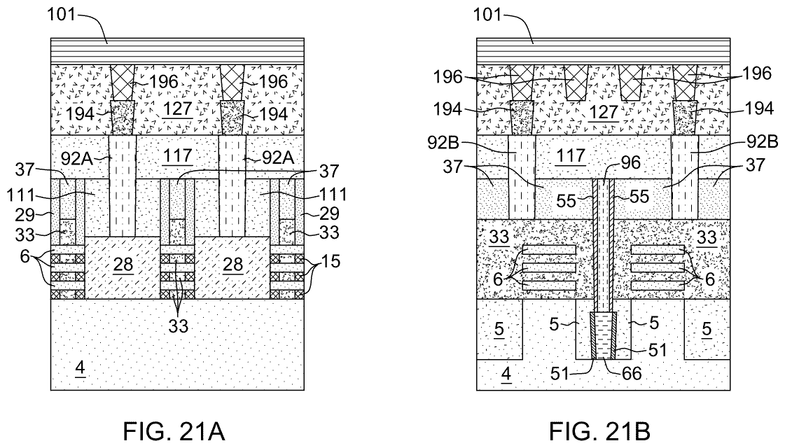

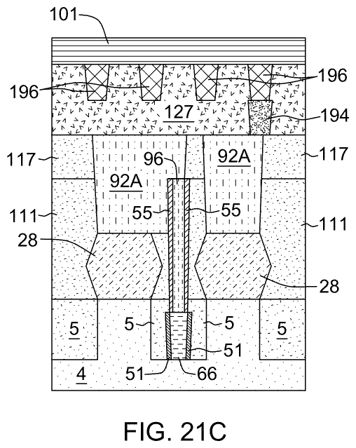

Each of FIG. 21A depicting a cross-sectional view X1-X1 of the semiconductor structure, FIG. 21B depicting a cross-sectional view Y1-Y1 of the semiconductor structure, and FIG. 21C depicting a cross-sectional view Y2-Y2 of the semiconductor structure after removing substrate 2 and etch stop 3, in accordance with an embodiment of the present invention. Using known semiconductor grinding and/or etching processes, substrate 2 and etch stop 3 are removed. The bottom surface of semiconductor material 4 is exposed.

As known to one skilled in the art, in some cases, using typical semiconductor processing, a carrier wafer (not depicted) would be bonded to front side interconnect wiring 101, and the semiconductor structure would be flipped so that substrate 2 is the top surface before wafer grinding and etching of substrate 2 and etch stop 3. For consistency, the semiconductor structures of FIG. 21A, 21B, 21C-FIGS. 27B and 27C are not depicted as flipped.

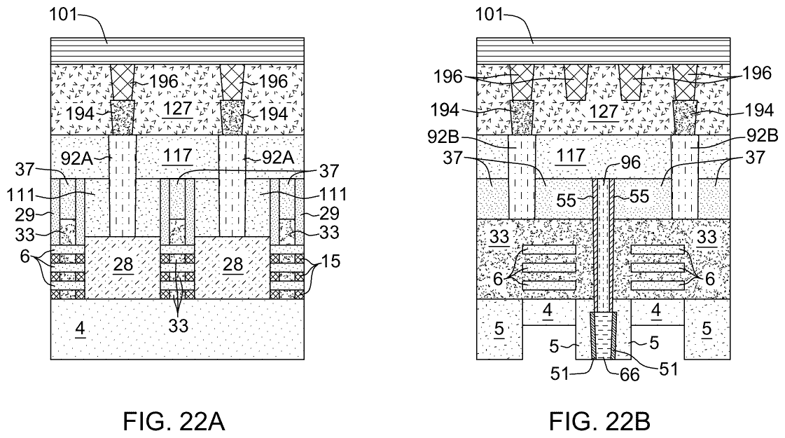

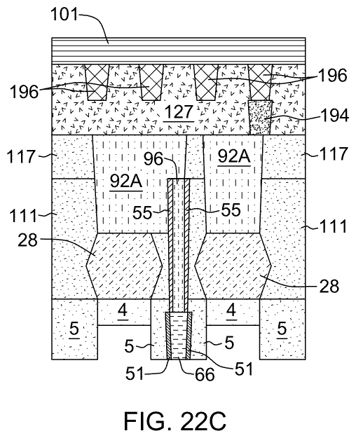

FIG. 22A depicts a cross-sectional view X1-X1 of the semiconductor structure after removing portions of semiconductor material 4, in accordance with an embodiment of the present invention. A semiconductor substrate grind and/or a wet etching process removes the bottom portion of semiconductor material 4. After the semiconductor grinding/etching, a wet etch of semiconductor material 4 further removes another portion of semiconductor material 4. The remaining portion of semiconductor material 4 is under S/D 28 and gate 33, as depicted.

FIG. 22B depicts a cross-sectional view Y1-Y1 of the semiconductor structure removing portions of semiconductor material 4, in accordance with an embodiment of the present invention. Using the processes discussed (e.g., wafer grinding and/or etching) with respect to FIG. 22A, semiconductor material 4 is removed from the bottom surface of STI 5, and the second etching process of semiconductor material 4 recesses portions of semiconductor material 4 between the three STI 5. After completing the two semiconductor etching processes, the bottom portions of the sidewall of STI 5, the bottom surfaces of STI 5, placeholder 66 with liner 51, and the remaining portions of semiconductor material 4 are exposed. As depicted, the exposed bottom surface of the remaining portion of semiconductor material 4 is above the bottom surface of STI 5 and below the top surface of placeholder 66 and STI 5.

FIG. 22C depicts a cross-sectional view Y2-Y2 of the semiconductor structure after removing portions of semiconductor material 4, in accordance with an embodiment of the present invention. Using the processes discussed with respect to FIG. 22B, semiconductor material 4 is removed from STI 5, and the second etching process of semiconductor material 4 recesses portions of semiconductor material 4 between the portions of STI 5. As depicted, the exposed surface of the remaining portion of semiconductor material 4 is above the bottom surface of STI 5 and below the top surface of placeholder 66 and STI 5.

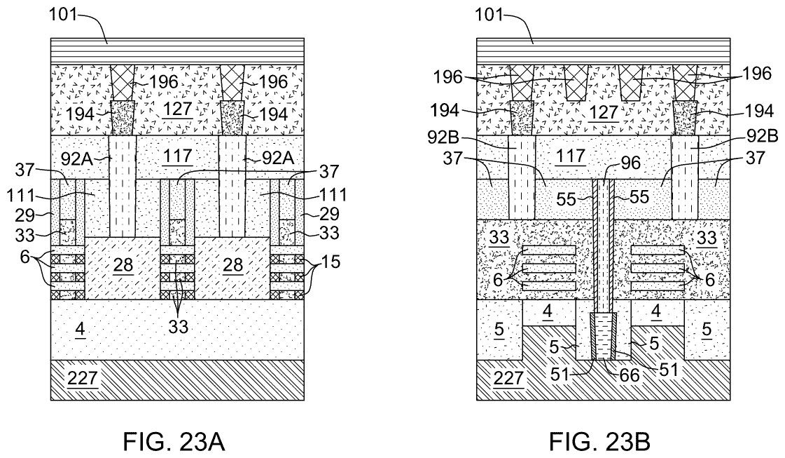

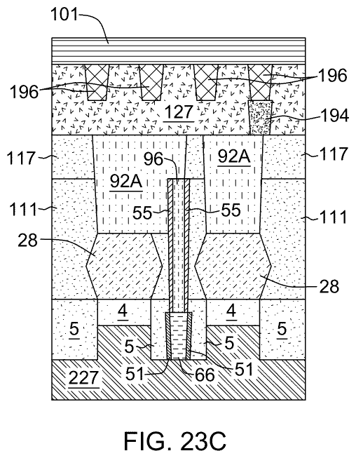

Each of FIG. 23A depicting a cross-sectional view X1-X1 of the semiconductor structure, FIG. 23B depicting a cross-sectional view Y1-Y1 of the semiconductor structure, and FIG. 23C depicting a cross-sectional view Y2-Y2 of the semiconductor structure illustrate the semiconductor structure after depositing the backside ILD 227, in accordance with an embodiment of the present invention. Backside ILD 227 can be deposited on the exposed bottom surfaces of FIGS. 23A, 23B, and 23C, as depicted.

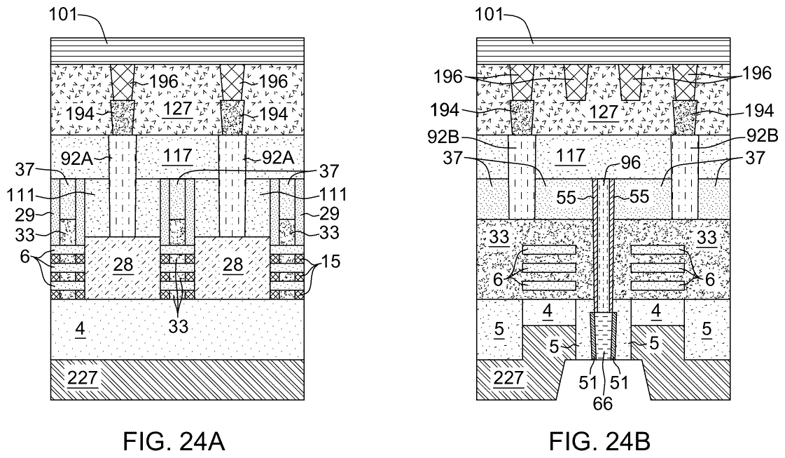

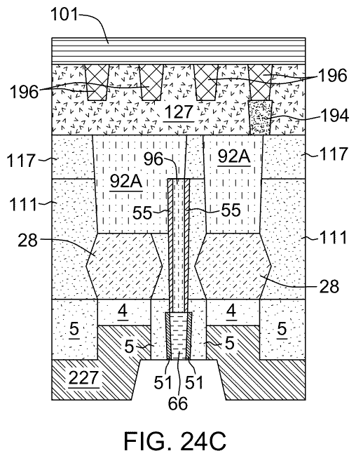

FIG. 24A depicts a cross-sectional view X1-X1 of the semiconductor structure after patterning and etching openings in the backside ILD in FIGS. 24B and 24C, in accordance with an embodiment of the present invention. As depicted, FIG. 24A is the same as FIG. 23A.

Using known patterning and etching processes, a trench or opening in backside ILD 227 can be formed under placeholder 66 with liner 51 in FIG. 24B depicting a cross-sectional view Y1-Y1 of the semiconductor structure and in FIG. 24C depicting a cross-sectional view Y2-Y2 of the semiconductor structure, in accordance with an embodiment of the present invention. In both FIG. 24B and FIG. 24C, the trench or opening is wider than the middle STI 5 with placeholder 66.

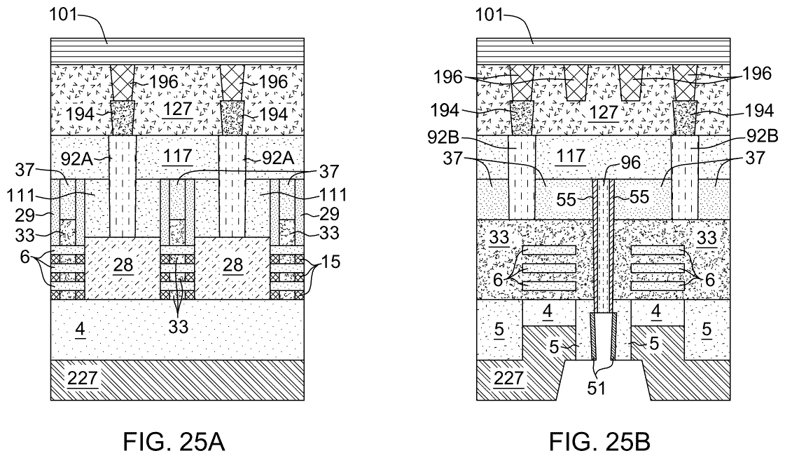

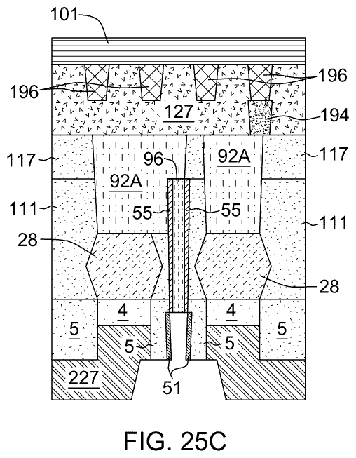

FIG. 25A depicts a cross-sectional view X1-X1 of the semiconductor structure after removing placeholder 66 in FIGS. 25B and 25C, in accordance with an embodiment of the present invention. As depicted, FIG. 25A is the same as FIG. 24A.

Using one or more known wet and/or a dry etching process (e.g., for SiGe), placeholder 66 is removed from inside liner 51 in FIG. 25B and in FIG. 25C where FIG. 25B depicts the cross-sectional view Y1-Y1 and FIG. 25C depicts the cross-sectional view Y2-Y2 of the semiconductor structure, in accordance with an embodiment of the present invention. The removal of placeholder 66 creates an opening with a height that is less than the height of STI 5. The top of the opening is below the bottom surface of gate 33 in FIG. 25B and below S/D 28 in FIG. 25C. As depicted in FIGS. 25B and 25BC, the top of the opening is level with the surface of the remaining semiconductor material 4 although the top of the opening may be higher or lower in other examples. The bottom of the opening is level with the bottom of the middle STI 5. The opening created by the removal of placeholder 66 joins the opening in ILD 227 created in FIGS. 25A and 25B.

FIG. 26A depicts a cross-sectional view X1-X1 of the semiconductor structure after depositing a metal material for connector via 294 and backside metal 296 in FIG. 26B and FIG. 26C, in accordance with an embodiment of the present invention. As depicted, FIG. 26A is the same as FIG. 25A.

FIG. 26B depicts a cross-sectional view Y1-Y1 of the semiconductor structure after depositing a metal material for connector via 294 and backside metal 296, in accordance with an embodiment of the present invention. As depicted, FIG. 26B includes the elements of FIG. 25B with connector via 294 and backside metal 296 where backside metal 296 can be the first metal layer of a BSPDN. Also, illustrated in FIG. 26B are widths X₁ and X₂ of the top and bottom surfaces, respectively of connector via 294.

In various embodiments, the metal material for connector via 294 and backside metal 296 is the same (e.g., is deposited in a single deposition process for both). The metal material can be any material suitable for a backside metal layer (e.g., Cu), for example, in a backside power delivery network (BSPDN). In various embodiments, the metal material for connector via 294 has an electrical conductivity greater than 3.0×10⁷ σ. In some embodiments, the metal material for connector via 294 has an electrical conductivity greater than 4.0×10⁷ σ at 20 degree Celsius such as copper or a copper alloy. Using the same metal for connector via 294 and backside metal 296 reduces interfaces between different metal materials and reduces any electrical discontinuities between different metal materials especially when the metal material is copper that is deposited in a single deposition process for both connector via 294 and backside metal 296.

Additionally, since connector via 294 replaces placeholder 66 which is formed in a front side etched trench, the width of the top surface of connector via 294 is larger than the width of power rail 96. Connector via 294 can be wider than a typical front side via or TSV connecting to backside metal 296 which reduces the electrical resistance of the path between S/D 28 and backside metal 296. Connector via 294 is centered in the middle STI 5.

In some embodiments, connector via 294 is composed of a different metal material (e.g., W, Co, or Ru). In this case, the metal deposited the first deposition process (e.g., ALD, CVD, or PVD) fills the opening surrounded by liner 55. A second metal deposition process can deposit backside metal 296 (e.g., a different metal such as Cu).

As depicted, X₁, the width of the top surface of connector via 294. As previously discussed in detail regarding the width X₁ of the top surface of placeholder 66 in FIG. 6, the width X₁ is wider than X₂, the width of the bottom surface of connector via 294 which results in a slightly trapezoidal cross-section of connector via 294. Providing a wider top surface of connector via 294 reduces the chance of misalignment between power rail 96. Forming a wider opening in backside ILD 227 for lines in backside metal 296 that contacts the bottom surface of placeholder 66 in the middle of STI 5 reduces possible misalignment between connector via 294 and backside metal 296 and allows a single backside metal deposition process to contact power rail 96 of the semiconductor structure front side metallization. In a conventional semiconductor structure with a BSPDN, a backside via or TSV with a much smaller diameter would typically connect to a buried power rail to the first backside metal layer of the BSPDN. Providing a larger diameter and a larger contact area of connector via 294 for the connection to power rail 96 improves the electrical performance (e.g., reduces the electrical resistance of the connection to power rail 96). Using connector via 294 for a direct connection between a power rail formed on the front side of the wafer to a backside metal layer reduces the number of connections between the front side wiring and the backside wiring. Reducing the number of connections reduces possible sources of misalignment between the connections from power rail 96 to backside metal 296 and in reducing connection misalignment, connector via 294 improves the semiconductor structure's electrical performance. Additionally, the direct connection between power rail 96 and backside metal 296 provides a shorter electrical path with fewer electrical discontinuities caused by additional backside via or TSV connections. The distance between power rail 96 and backside metal 296 is only the height of connector via 294 which is less than the height of the STI 5 (e.g., a small distance for a very short electrical path between the front side wafer metallization and the backside wafer metallization as depicted FIG. 26B and FIG. 26C).

FIG. 26C depicts a cross-sectional view Y2-Y2 of the semiconductor structure after depositing a metal material for connector via 294 and backside metal 296, in accordance with an embodiment of the present invention. Using the processes discussed above with respect to FIG. 26B, FIG. 26C can be formed where the leftmost S/D 28 connects by the left side contact 92A to power rail 96. Connector via 294 is centered in the middle STI 5. Connector via 294, as depicted, is centered directly below power rail 96 and above backside metal 296.

The semiconductor structure of FIG. 26C provides similar or the same advantages to the connection of connector via 294 directly to power rail 96 and backside metal 296 discussed above in detail with respect to FIG. 26B. As previously discussed, the direct connection of power rail 96 to backside metal 296 using connector via 294 reduces the electrical resistance of the connections between power rail 96 and backside metal 296 compared to a conventionally formed power rails and BSPDN. As previously discussed, the wider top surface of connector via 294 reduces misalignment that can occur in conventional backside via connections of the power rail to the BSPDN.

As depicted, the semiconductor structure of FIG. 26C has power rail 96 directly connects contact 92A (i.e., an S/D contact) to backside metal 296 using connector via 294 without the use of front side vias, backside vias, or through-silicon vias (TSVs) or nano TSVs (nTSVs) of typical connections to the BSPDN. Removing via connections and/or TSV connections in the electrical path from S/D 28 to backside metal 296 improves the electrical performance of the semiconductor devices.

The length or height of connector via 294 above backside metal 296 is equal to less than the height of STI 5. Accordingly, the length of the electrical path from power rail 96 to backside metal 296 is very short (e.g., less than the height of STI 5) and passes through the copper material of connector via 294 has a width that is greater than the width of power rail 96. The semiconductor structure of FIG. 26C results in improved electrical performance of the semiconductor structure from resistor-capacitor (RC) component or current-resistor (IR) drop compared to conventional semiconductor structures with power rails, TSVs, buried power rails with backside vias or nTSVs, or a combination of these to connect one or more source/drains to a BSPDN.

FIG. 27B depicts a cross-sectional view Y1-Y1 of the semiconductor structure without liner 51 on the middle STI 5, in accordance with an embodiment of the present invention. As depicted, FIG. 27B includes the elements of FIG. 26B without liner 51 and with connector via 394 replacing connector via 294. Without liner 51, connector via 394 in FIG. 27B is slightly wider than connector via 294 in FIG. 26B. Also, depicted in FIG. 27B is the width X₁₁ of the top surface of connector via 394 and the width, X₂₂ of the bottom surface of connector via 394. The width X₁₁ is greater than the width X₂₂. Additionally, the width X₁₁ is greater than the width₁ of connector via 294 in FIG. 26B. The increased width of connector via 394 compared to connector via 294 improves the electrical performance (e.g., less resistance) compared to connector via 294. and reduces potential misalignment or overlay errors.

The semiconductor structure of FIGS. 27B and 27C can be formed from the semiconductor structure of FIG. 4 with liner 31 above STI 5 and without liner 51 deposited on the sidewall of the middle STI 5 in FIG. 5. The cross-sectional view X1-X1 (not depicted) of the semiconductor structure without liner 51 on the middle STI 5 is the same as cross-sectional view X1-X1 depicted in FIG. 26A. The cross-sectional view X-1-X1 (not depicted) of the semiconductor structure depicted in FIG. 27B and FIG. 27C is the same as cross-sectional view X1-X1 depicted in FIG. 26A. After performing the processes discussed with respect to FIGS. 5 and 6 on the semiconductor structure of FIG. 4 without liner 51 on the middle STI 5 results not having liner 55 around placeholder 66 in FIG. 7. After performing the processes discussed with respect to FIGS. 7-26C, results in the wider connector via 394.

Additionally, providing a wider top surface of connector via 394 further reduces the possibility of misalignment between power rail 96 and connector via 394 where the misalignment also increases the electrical resistance of connector via 394 to metal layer 396 of the BSPDN. In other words, the wider connector via 394 improves the electrical performance of the semiconductor device and the resulting semiconductor chip. Connector via 394 provides the advantages of the semiconductor structure with connector via 294 discussed in detail with respect to FIG. 26B.

FIG. 27C depicts a cross-sectional view Y2-Y2 of the semiconductor structure without liner 51, in accordance with an embodiment of the present invention. As depicted, FIG. 27C includes the elements of FIG. 26C without liner 51 and with connector via 394 replacing connector via 294. Without liner 51, connector via 394 in FIG. 27C is slightly wider than connector via 294 in FIG. 26C. Also, depicted in FIG. 27C is the width X₁₁ of the top surface of connector via 394 and the width, X₂₂ of the bottom surface of connector via 394.

The semiconductor structure of FIG. 27C provides the advantages discussed in detail above with respect to FIG. 27B and the advantages of connector via 294 discussed in detail with respect to FIG. 26B and FIG. 26C.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a power rail; and
a connector via connecting the power rail to a backside metal layer, wherein the connector via is within a shallow isolation trench.

2. The semiconductor structure of claim 1, wherein the connector via has a top surface that is wider than a bottom surface of the connector via.

3. The semiconductor structure of claim 1, wherein the connector via has a top surface that is wider than a bottom of the connector via.

4. The semiconductor structure of claim 3, wherein the backside metal layer has a top surface contacting the bottom surface of the connector via and a bottom surface of the shallow isolation trench.

5. The semiconductor structure of claim 1, wherein the backside metal layer is a first metal layer in a backside power delivery network.

6. The semiconductor structure of claim 1, wherein the connector via is composed of a metal material with an electrical conductivity greater than 4.0×10⁷ σ.

7. The semiconductor structure of claim 1, wherein the connector via and the backside metal layer are composed of same metal material.

8. The semiconductor structure of claim 1, wherein the power rail has a first portion adjacent to a source/drain, wherein a top surface of the first portion of the power rail contacts a portion of a source/drain contact, and wherein a bottom surface of the power rail contacts the connector via.

9. The semiconductor structure of claim 1, further comprising:
two source/drains of two adjacent semiconductor devices, wherein a first portion of the power rail is between the two source/drains;
two source/drain contacts, wherein one source/drain contact connects to connector via by the first portion of the power rail and a second source/drain contact connects to the at least one metal layer through a first via and to one or more front side interconnect layers;
two gates of two adjacent semiconductor device, wherein a second portion of the power rail is between the two gates; and
two gate contacts each connects by a second via to: (i) at least a metal layer and (ii) the one or more front side interconnect layers.

10. The semiconductor structure of claim 9, wherein the two gates are electrically isolated from the power rail by a liner surrounding a sidewall of the power rail.

11. A connector via comprising:
a connector via with a trapezoidal cross-section with a top surface that has a larger width than a width of a bottom surface of the connector via, wherein the connector via is copper;
a portion of a power rail directly above and contacting the top surface of the copper element, wherein the power rail extends between one or more gates of at least two adjacent semiconductor devices; and
a backside metal layer contacting a bottom surface of the copper element, wherein the copper element is a connector via.

12. The connector via of claim 11, wherein the connector via extends between one or more gates of the at least two adjacent semiconductor devices.

13. The connector via of claim 11, wherein the connector via is below and parallel to active regions of the at least two adjacent semiconductor devices.

14. The connector via of claim 11, wherein the power rail has a width that is less than the width of the top surface of the connector via, and wherein the connector via has a bottom surface with a width that is less than a width of a top surface of the backside metal layer.

15. The connector via of claim 11, wherein the connector via and the backside metal layer are composed of copper.

16. The connector via of claim 11, wherein the connector via is centered in a shallow isolation trench.

17. A connector via comprising:
a connector via with a trapezoidal cross-section is a connector via with a larger width of a top surface than a width of a bottom surface, wherein the connector via is copper;
a liner on a sidewall of the connector via;
a portion of a power rail directly above and contacting a top surface of the connector via, wherein the power rail is between one or more gates of at least two adjacent semiconductor devices; and
a backside metal layer contacting a bottom surface of the connector via.

18. The connector via of claim 17, wherein the connector via extends between two gates of the at least two adjacent semiconductor devices.

19. The connector via of claim 17, wherein the connector via is below and parallel to active regions of the at least two adjacent semiconductor devices.

20. The connector via of claim 17, wherein the power rail has a width that is less than a width of the top surface of the connector via, and wherein the connector via has a bottom surface with a width that is less than a width of a top surface of the backside metal layer.

21. The connector via of claim 17, wherein the connector via and the backside metal layer are composed of a same metal material.

22. The connector via of claim 17, wherein the connector via is centered in a shallow isolation trench, and wherein a top surface of the shallow isolation trench is above a top surface of the connector via.

23. A method of forming a semiconductor structure comprising:
etching a hole between two portions of a nanosheet stack to a bottom of a shallow isolation trench (STI);
depositing a liner;
removing horizontal portions of the liner with a directional etching process;
growing a placeholder using epitaxy in a portion of the hole, wherein a top surface of the placeholder is below a top surface of the STI;
depositing and recessing an oxide, wherein a portion of the oxide remains on the placeholder;
forming source/drains using epitaxy;
forming replacement metal gates;
forming a power rail with a power rail liner contacting the placeholder;
forming gate and source/drain contacts, wherein one source/drain contact connects to the power rail;
removing a backside substrate, an etch stop layer, and portion of a semiconductor material;
removing a portion of a deposited backside interlayer dielectric exposing a bottom surface of the placeholder;
removing the placeholder;
depositing and patterning a backside interlayer dielectric; and
depositing a metal layer on the backside interlayer dielectric and in the hole created by the removal of the placeholder, wherein a portion of the metal layer in the hole created by the removal of the placeholder is a connector via and a portion of the metal layer in the backside interlayer dielectric is a backside metal layer.

24. The method of claim 23, wherein:
the backside metal layer and the connector via are composed of copper;
the connector via resides in the STI and is below a top surface of the STI; and
the connector via connects the power rail to the backside metal layer of a backside power delivery network.

25. A method of forming a semiconductor structure comprising:
etching a hole between two portions of a nanosheet stack to a bottom of a shallow isolation trench (STI);
depositing a first liner;
removing horizontal portions of the first liner with a directional etching process;
depositing a second liner;
removing horizontal portions of the second liner;
growing a placeholder using epitaxy in a portion of the hole, wherein a top surface of the placeholder is below a top surface of the STI;
depositing and recessing an oxide, wherein a portion of the oxide remains on the placeholder;
forming source/drains using epitaxy;
forming replacement metal gates;
forming a power rail with a liner contacting the placeholder;
forming gate and source/drain contacts, wherein one source/drain contact connects to the power rail;
removing a backside substrate, an etch stop layer, and portion of a semiconductor material;
removing a portion of a deposited backside interlayer dielectric exposing a bottom surface of the placeholder;
removing the placeholder;
forming a connector via by depositing a metal in a hole created by the removed placeholder; and
forming a backside metal layer on the connector via, wherein the connector via connects the backside metal layer to the power rail.
